(19) United States
(12) Patent Application Publication
(10) Pub. No.: US 2026/0165150 A1
(43) Pub. Date: Jun. 11, 2026

(54) METHOD FOR PROCESSING INSULATION LAYER, METHOD FOR PRODUCING REDISTRIBUTION LAYER, AND PROCESSING APPARATUS

(71) Applicant: Panasonic Intellectual Property Management Co., Ltd., Osaka (JP)

(72) Inventors: TAKAHIRO KUMAKAWA, Kyoto (JP); KIYOKAZU ITOI, Osaka (JP)

(21) Appl. No.: 19/404,057

(22) Filed: Dec. 1, 2025

(30) Foreign Application Priority Data
Dec. 5, 2024 (JP) 2024-212224

(51) Int. Cl. H10W 70/05; H10P 14/47; H10P 14/60; H10P 72/00; H10P 95/00; H10W 70/06

(52) U.S. Cl. CPC H10W 70/095; H10P 14/48; H10P 14/662; H10P 72/0438; H10P 95/04; H10W 70/06

(57) ABSTRACT

A method for processing an insulation layer and using an imprinting mold including the plurality of pillars projecting from a second surface of a body, includes: an insulation layer formation step of forming the insulation layer on an upper surface of a base; a first material adhesion step of causing a first material to adhere to a tip of the pillar; a pressurization step of pressing and pressurizing the imprinting mold against the insulation layer to cause the first material to reach the upper surface of the base; a mold release step of extracting the imprinting mold from the insulation layer to form a via hole at a position in the insulation layer where a corresponding the pillar is inserted; and a curing step of curing the insulation layer. The first material has an elastic modulus equal to or lower than an elastic modulus of the insulation layer.

### BACKGROUND

### 1. Technical Field

The present disclosure relates to a method for processing an insulation layer, in particular, an insulation layer serving as a base of a redistribution layer, a method for producing a redistribution layer, and a processing apparatus.

### 2. Description of the Related Art

In recent years, miniaturization, high-functionalization, and multi-functionalization of electronic components and devices have progressed, and to respond to these needs, densification of elements and narrower pitches of wirings in semiconductor chips mounted on electronic components and the like are desired.

For example, an interposer, which is a wiring board inserted between a semiconductor chip and a mounting substrate, plays a role of effectively connecting semiconductor devices and modules having different shapes and pitches. Thus, a high-density circuit can be formed by using an interposer in an electronic component or the like.

In the case of forming a wiring or a via in the interposer, for example, a groove or a via hole is formed inside an insulation layer formed on the upper surface of a base by etching, photolithography, or the like, and then metal plating or the like is applied inside the groove or the via hole to form a wiring or a via. In the interposer, the via connects the wirings of different layers to each other or connects the wirings and the land electrodes provided on the front surface and/or the back surface of the interposer.

On the other hand, in recent years, an imprinting method has attracted attention as a wiring formation method in place of etching or photolithography. The imprinting method is a method of forming a groove or a via hole by transferring a pattern to an insulation layer made of a resin material and formed on a surface of a base using an imprinting mold on which a fine pattern is formed and curing the insulation layer (see, for example, Patent Literature (PTL) 1). In this case, the insulation layer after curing is not removed, and it becomes a part of a redistribution layer constituting an interposer.

According to the imprinting method disclosed in PTL 1, via holes can be collectively formed with high accuracy.

PTL 1: Japanese Translation of PCT International Application Publication No. 2022-508102

### SUMMARY

To achieve the object described above, a method for processing an insulation layer according to one aspect of the present disclosure is a method for processing an insulation layer using an imprinting mold. The imprinting mold includes at least a body and a plurality of pillars. The plurality of pillars project from at least a second surface of the body. The method includes at least an insulation layer formation step, a first material adhesion step, a pressurization step, a mold release step, and a curing step. In the insulation layer formation step, an insulation layer is formed on an upper surface of a base. In the first material adhesion step, a first material is caused to adhere to a tip of each of the plurality of pillars. In the pressurization step, the imprinting mold is pressed and pressurized against the insulation layer to cause the first material to reach the upper surface of the base. In the mold release step, the imprinting mold is extracted from the insulation layer to form a via hole at a position in the insulation layer where a corresponding one of the plurality of pillars is inserted. In the curing step, the insulation layer is cured. The first material has an elastic modulus equal to or lower than an elastic modulus of the insulation layer.

A method for producing a redistribution layer according to one aspect of the present disclosure includes at least a recess formation step, a pretreatment step, a plating step, and a planarization step. In the recess formation step, at least a plurality of via holes are formed in the insulation layer formed on the upper surface of the base by using the method for processing the insulation layer. In the pretreatment step, a barrier layer and a seed layer are formed on a surface of the insulation layer including an inner wall surface of each of the plurality of via holes. In the plating step, metal plating is performed on the surface of the seed layer to embed a metal in each of the plurality of via holes. In the planarization step, the metal embedded in the plurality of via holes are processed into a plurality of vias by removing the metal formed on an upper surface of the insulation layer. The insulation layer and the plurality of vias constitute the redistribution layer.

A processing apparatus according to one aspect of the present disclosure is a processing apparatus for forming at least a plurality of via holes in an insulation layer formed on an upper surface of a base. The processing apparatus includes at least a first unit, a second unit, and a mold holder. The first unit includes at least a first stage and a first material supply mechanism that supplies a first material having an elastic modulus equal to or lower than an elastic modulus of the insulation layer to cause the first material to spread in a predetermined range on an upper surface of the first stage. The second unit includes at least a second stage for placing the base on which the insulation layer is formed and a heating mechanism for heating the second stage. The mold holder is fitted with a first moving mechanism that moves the mold holder at least between the first unit and the second unit, and a second moving mechanism that moves the mold holder toward each of the first stage and the second stage. An imprinting mold is detachably attached to a lower end of the mold holder. The imprinting mold includes at least a body and a plurality of pillars projecting from a second surface of the body. In the first unit, the first material is caused to adhere to a tip of each of the plurality of pillars. In the second unit, a plurality of via holes are formed in the insulation layer by pressing and pressurizing the imprinting mold to which the first material is adhering against the insulation layer, using the mold holder.

### BRIEF DESCRIPTION OF THE DRAWINGS

FIG. 1A is a schematic sectional view of a main part of an interposer;

FIG. 1B is an enlarged view of a portion surrounded by the broken line 1B in FIG. 1A;

FIG. 1C is an enlarged view of a portion surrounded by the broken line 1C in FIG. 1B;

FIG. 2 is a schematic configuration diagram of a processing apparatus according to a first exemplary embodiment;

FIG. 3 is a schematic sectional view of an imprinting mold;

FIG. 4 is a schematic view for describing a step of adhering and curing a first material to a tip of a pillar;

FIG. 5A is a schematic view for describing a method for processing an insulation layer according to the first exemplary embodiment;

FIG. 5B is a schematic view for describing a step subsequent to FIG. 5A;

FIG. 6A is an enlarged view of an insulation layer in which a groove and a via hole are formed;

FIG. 6B is a schematic view for describing a conventional problem, corresponding to FIG. 6A;

FIG. 6C is another schematic view for describing a conventional problem, corresponding to FIG. 6A;

FIG. 7 is an enlarged view of a portion including a tip of a pillar in a pressurization step according to the first exemplary embodiment;

FIG. 8 is a schematic view illustrating an outline of a via hole formation step according to the first exemplary embodiment;

FIG. 9 is a schematic view illustrating an outline of the via hole formation step according to the first exemplary embodiment, which is a schematic view illustrating a case where a deformation amount of an adhering substance is large;

FIG. 10A is a schematic view for describing a method for producing a redistribution layer according to the first exemplary embodiment;

FIG. 10B is a schematic view for describing a step subsequent to FIG. 10A;

FIG. 11 is a schematic view illustrating an outline of a via hole formation step according to a modification;

FIG. 12 is a schematic sectional view of a tip of another pillar according to the modification;

FIG. 13 is a schematic view illustrating an outline of a via hole formation step according to a second exemplary embodiment;

FIG. 14 is a schematic view illustrating an outline of another via hole formation step according to the second exemplary embodiment;

FIG. 15 is a schematic view illustrating an outline of a via hole formation step according to a third exemplary embodiment; and

FIG. 16 is a schematic sectional view of a via hole after execution of a pretreatment step according to the third exemplary embodiment.

### DETAILED DESCRIPTIONS

When a via hole is formed in a redistribution layer by photolithography and etching, a mask pattern for forming a via hole is formed, and after exposure and development treatment are performed, the remaining film of the insulation layer hardly remains at the bottom of the via hole. The remaining residue can also be removed through a descum treatment. PTL 1 also discloses that an insulation layer remaining at the bottom of a via hole after imprinting is removed by a similar descum treatment.

However, actually, warpage or undulation may occur on the surface of the substrate on which the insulation layer is formed. In addition, the land electrode provided on the base may be recessed because of dishing or the like. In addition, the flatness of the imprinting mold is not sufficient, and the depth of the via hole formed in the insulation layer during imprinting may vary.

When these events occur, the tip of a pillar provided in the imprinting mold does not reach the surface of the base or the land electrode during imprinting, and an insulation layer having a certain thickness remains on the surface of the base or the land electrode.

When the insulation layer remains with a predetermined thickness or larger thickness like this, the insulation layer cannot be completely removed through the descum treatment, and the bottom of the via is not exposed in the subsequent metal plating step, which may cause a connection failure with the base of the lower layer or the redistribution layer.

The present disclosure has been made in view of such a point, and an object of the present disclosure is to provide a method for processing an insulation layer, a method for producing a redistribution layer, and a processing apparatus capable of reducing the thickness of a remaining film at the bottom of a via hole provided in an insulation layer of a redistribution layer to a value less than or equal to a predetermined value.

Hereinafter, an exemplary embodiment of the present disclosure will be described with reference to the drawings. The following description of a preferred exemplary embodiment is merely exemplary in nature, and is not intended to limit the present disclosure, its applications, or its use.

### First Exemplary Embodiment

### [Configuration of Interposer]

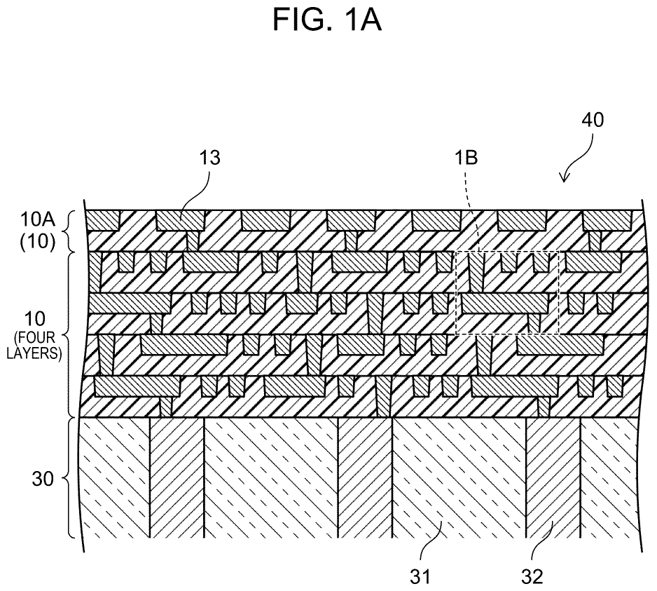

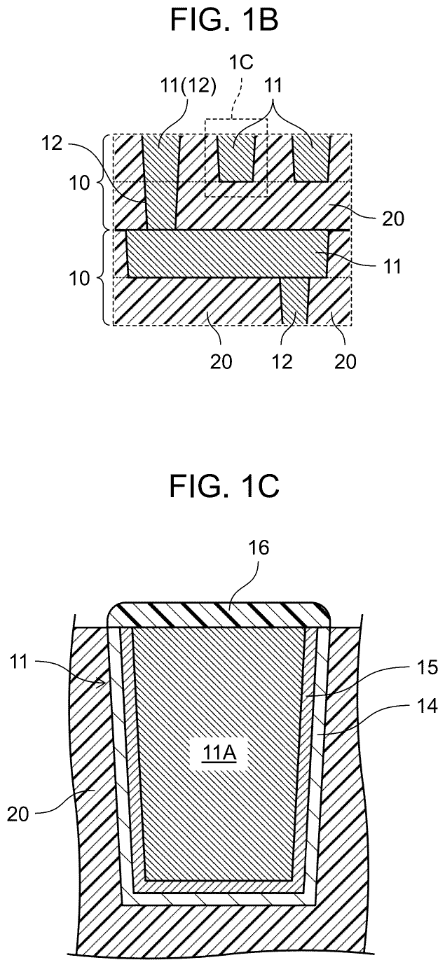

FIG. 1A is a schematic sectional view of a main part of an interposer. FIG. 1B is an enlarged view of a portion surrounded by the broken line 1B in FIG. 1A. FIG. 1C is an enlarged view of a portion surrounded by the broken line 1C in FIG. 1B.

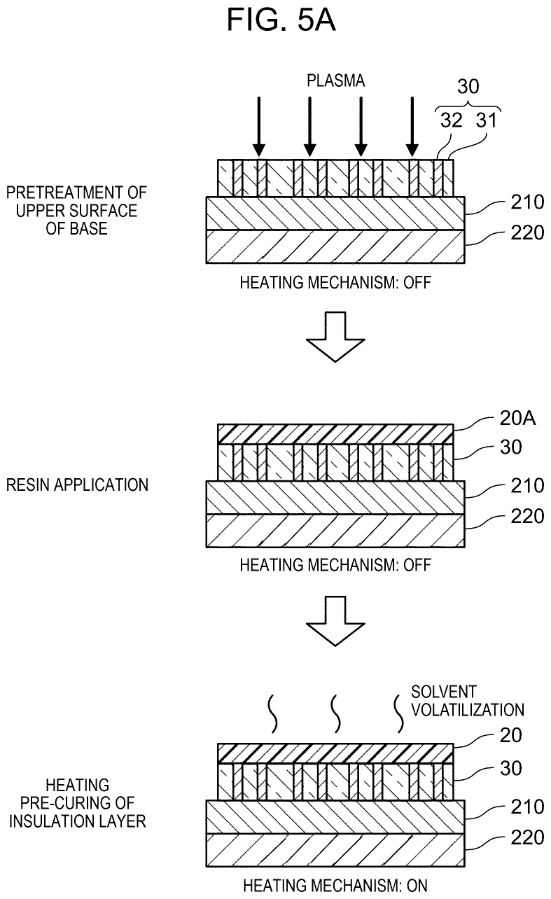

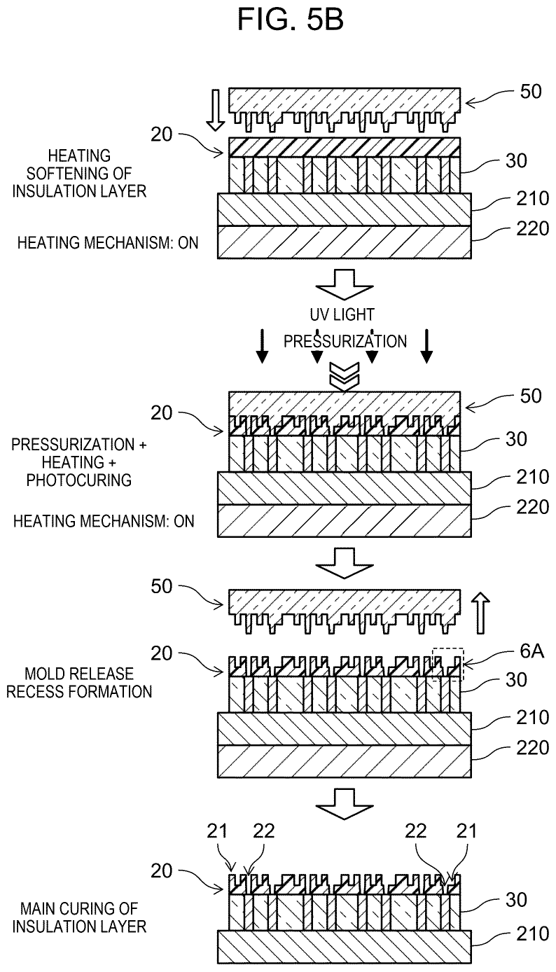

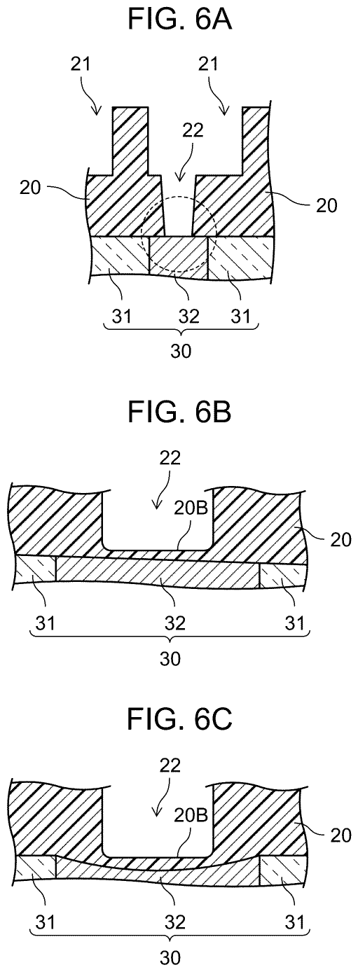

In interposer 40, the side on which redistribution layer 10A is provided is referred to as an upper side, and the side on which base 30 is provided is referred to as a lower side. In redistribution layer 10, the side on which a surface of wiring 11 is exposed is referred to as an upper side, and the opposite side is referred to as a lower side. In the insulation layer, the side on which a surface of groove 21 (see FIGS. 5B and 6A) is exposed is referred to as an upper side, and the opposite side is referred to as a lower side.

Interposer 40 illustrated in FIG. 1A is a wiring structure in which five redistribution layers 10 are laminated on an upper surface of core base 30 (hereinafter, it may be simply referred to as base 30.). In redistribution layer 10A positioned at the uppermost layer, only pad electrode 13 for electrically connecting with an electrical element, a wiring board, or a circuit board (none of which is illustrated) is exposed on the upper surface. The number of redistribution layers 10 provided in interposer 40 is not particularly limited to the example illustrated in FIG. 1A. The number of layers may be less than five, and for example, may be one. The number of layers may be more than five. The number of layers may be appropriately changed according to the number of elements or the like to be connected to interposer 40.

Core base 30 is a wiring structure in which a plurality of through glass via (TGV) electrodes 32 penetrate glass base 31. A plurality of land electrodes (not illustrated) provided to cover TGV electrodes 32 are disposed on the upper surface of core base 30, and via 12 of lowermost redistribution layer 10 is electrically connected to the land electrodes. A plurality of other land electrodes (not illustrated) provided to cover TGV electrodes 32 are also disposed on the lower surface of core base 30. In many cases, each of the plurality of land electrodes provided on the lower surface of core base 30 is provided with a projection electrode (not illustrated) for electrical connection with an external substrate. The upper surface and/or the lower surface of TGV electrode 32 may function as a land electrode.

As illustrated in FIG. 1B, redistribution layer 10 is disposed in a state where a plurality of wirings 11 and vias 12 are embedded in insulation layer 20. The upper surface of wiring 11 is flush with the upper surface of insulation layer 20. The lower surface of via 12 is flush with the lower surface of insulation layer 20. Although not illustrated in FIG. 1A or 1B, via 12 penetrating insulation layer 20, whose upper surface and lower surface are exposed, may be provided in redistribution layer 10. Via 12 exposed on the lower surface of redistribution layer 10 is connected to wiring 11 of redistribution layer 10 in contact with the lower surface. In redistribution layer 10 in contact with core base 30, via 12 exposed on the lower surface is connected to the land electrode or TGV electrode 32 provided on the upper surface of core base 30.

In addition, as illustrated in FIG. 1C, wiring 11 is a conductor that is provided in insulation layer 20, in which metal layer 11A made of copper (Cu) is embedded in groove 21 whose surface is covered with laminated structure of barrier layer 14 and seed layer 15. In wiring 11, the upper surface, which is an exposed surface, is covered with surface protective layer 16 in place of the above-described laminated structure. Although not illustrated, via 12 has a similar structure. However, surface protective layer 16 is not provided for via 12.

Barrier layer 14 suppresses occurrence of a short circuit inside redistribution layer 10 due to diffusion of copper constituting metal layer 11A into insulation layer 20. Barrier layer 14 also functions as an adhesion layer with insulation layer 20. Barrier layer 14 is made of, for example, a high-melting-point metal such as TaN, TiN, or cobalt (Co) or a compound of these metals, and may have a structure in which layers of different materials are laminated. Seed layer 15 functions as a growth base layer when copper electroplating described later is performed. Usually, when copper plating is performed, seed layer 15 is a thin film of the same copper. Surface protective layer 16 is provided to prevent oxidation and corrosion of metal layer 11A, that is, copper, during the production process or after the production. Surface protective layer 16 is, for example, an inorganic insulation film such as SiCN. However, the protective film is not limited to this example, and an inorganic conductive film such as TaN or TiN may be used as surface protective layer 16. When the width of wiring 11 is as wide as more than or equal to 5 μm, for example, surface protective layer 16 may be omitted. To prevent corrosion of metal layer 11A, a corrosion inhibitor may be applied to the upper surface of wiring 11.

Interposer 40 is used to electrically connect a wiring board or a circuit board and one or a plurality of semiconductor elements. In particular, interposer 40 is useful when the semiconductor elements are in multi-pin structure with narrow pad pitches. Examples of such a semiconductor element include a high-performance LSI such as a central processing unit (CPU) or a graphic processing unit (GPU), and a large-scale memory such as a high bandwidth memory (HBM).

On the other hand, in many cases, as illustrated in FIG. 1A, it is necessary to provide a plurality of redistribution layers 10 in interposer 40, and the number of production steps is enormous. Thus, the production yield tends to decrease, and the production cost tends to increase.

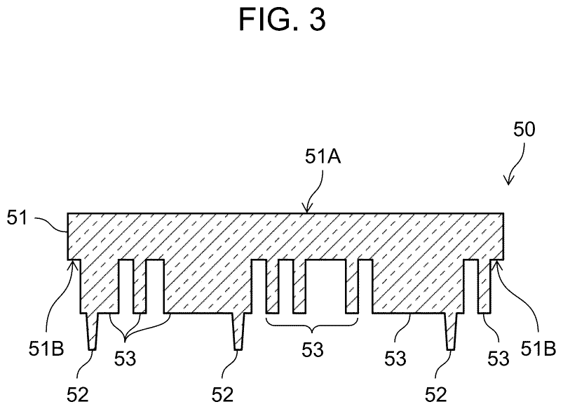

Thus, the inventors of the present application have studied a method in which a plurality of grooves 21 and a plurality of via holes 22 (see FIGS. 5B and 6A) are collectively and simultaneously formed in insulation layer 20 using multi-stage imprinting mold 50 (see FIG. 3), and copper is embedded in the grooves and the via holes. With this method, the number of production steps of redistribution layer 10, and thus the number of production steps of interposer 40 can be reduced.

On the other hand, the inventors of the present application have found that, when via hole 22 is formed using imprinting mold 50, the bottom of the via hole 22 does not open in some cases, and an insulation layer having a certain thickness may remain. Hereinafter, equipment and a method for solving the problem of the present disclosure will be described in order including a detailed description of this phenomenon.

### [Overview of Processing Apparatus]

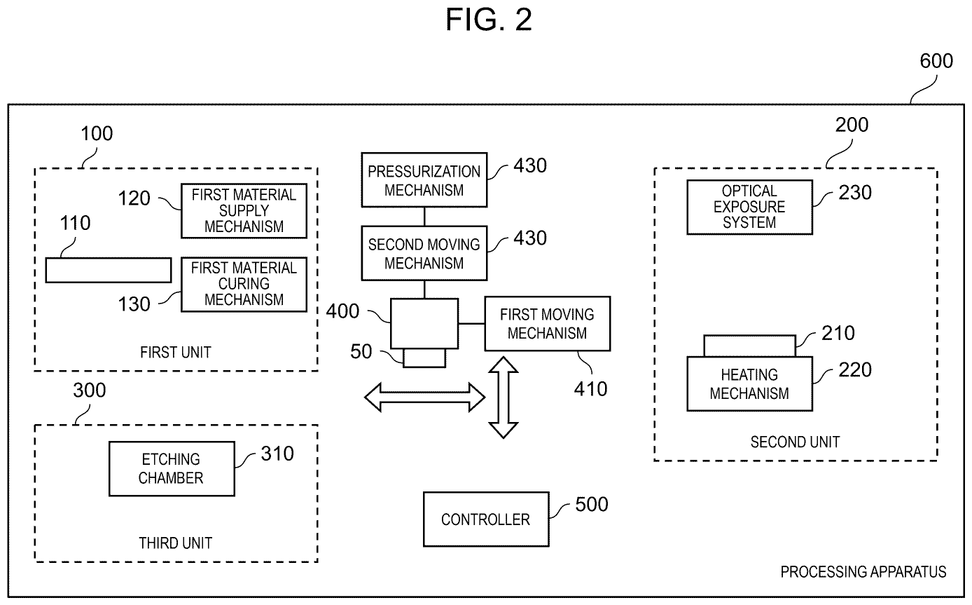

FIG. 2 is a schematic configuration diagram of a processing apparatus according to a first exemplary embodiment. FIG. 3 is a schematic sectional view of an imprinting mold.

Processing apparatus 600 illustrated in FIG. 2 includes first to third units 100, 200, 300, mold holder 400, and controller 500. These are accommodated in a housing (not illustrated). Each of first to third units 100, 200, 300 may have a housing, and each component described later may be accommodated in the housing.

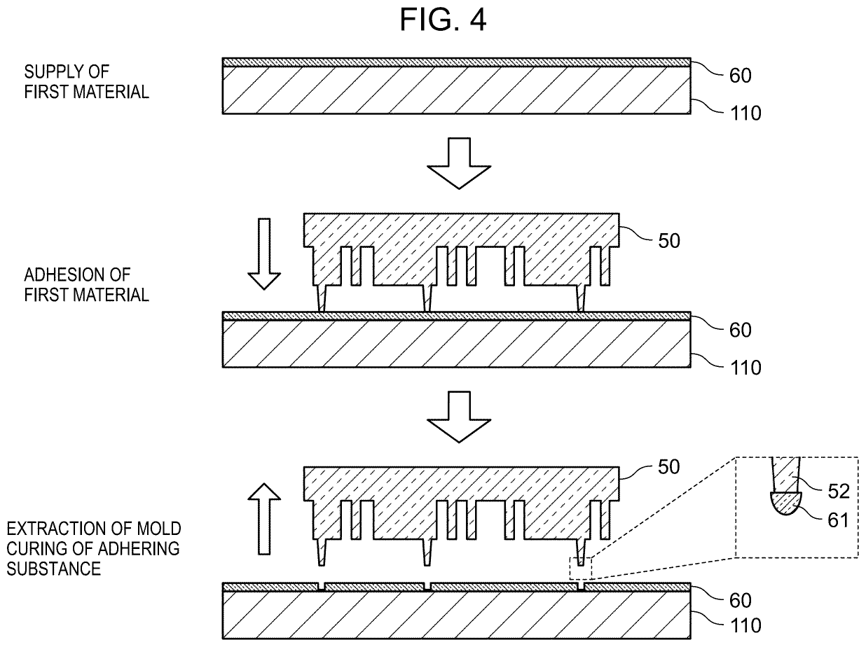

First unit 100 includes first stage 110 having a flat plate shape and first material supply mechanism 120. First material supply mechanism 120 supplies first material 60 (see FIG. 4) such that first material 60 spreads over a predetermined range on the upper surface of first stage 110. First material supply mechanism 120 supplies first material 60 to the upper surface of first stage 110 such that the thickness of first material 60 is uniform in the spread range.

First material 60 is made of a material containing a resin, and is supplied to the upper surface of first stage 110 in a liquid state or a highly fluid state. Alternatively, first material 60 processed into a sheet shape may be disposed on the upper surface of first stage 110. The configuration of first material supply mechanism 120 is appropriately selected according to the supply method and the supply form of first material 60 and the supply range. For example, when liquid first material 60 is supplied over the entire upper surface of first stage 110, first material supply mechanism 120 may be a spin coater used in semiconductor manufacturing or the like. When first material 60 is partially supplied to the upper surface of first stage 110, first material supply mechanism 120 may be an inkjet coater. First material supply mechanism 120 may be a spray coater. As described above, when first material 60 is a sheet material, first material supply mechanism 120 may be used as a transfer apparatus for the sheet.

First unit 100 includes first material curing mechanism 130. First material curing mechanism 130 is a mechanism for curing first material 60 adhering to pillar 52. The curing method of first material 60 in first material curing mechanism 130 is appropriately selected according to the properties and the like of the resin constituting first material 60. For example, when first material 60 is made of a photocurable resin material, first material curing mechanism 130 is an optical exposure system that irradiates first material 60 adhering to pillar 52 with UV light. When first material 60 is made of a thermosetting resin material, first material curing mechanism 130 is a heating mechanism that heats first material 60 adhering to pillar 52. First material curing mechanism 130 may be a mechanism for drying and curing the first material adhering to pillar 52, for example, a hot air blowing mechanism.

Second unit 200 includes second stage 210 having a flat plate shape for placing base 30 on which insulation layer 20 is formed, and heating mechanism 220 for heating the second stage. Second unit 200 includes optical exposure system 230 that irradiates insulation layer 20 with light, in this case, UV light. When the imprinting step (pressurization step) described later is thermal imprinting, optical exposure system 230 may be omitted.

Second unit 200 may have a mechanism that performs a surface treatment (not illustrated; hereinafter, may be referred to as surface treatment mechanism) on base 30 before insulation layer 20 is formed. The surface treatment mechanism may be provided outside second unit 200.

Third unit 300 includes etching chamber 310. In etching chamber 310, after insulation layer 20 is processed as described later, that is, after a plurality of grooves 21 and a plurality of via holes 22 are formed in insulation layer 20, adhering substance 61 (see FIG. 4) adhering to imprinting mold 50 is removed. Third unit 300 may be provided outside processing apparatus 600.

Mold holder 400 is a holding member to which imprinting mold 50 is detachably attached at its lower end. Mold holder 400 is fitted with first moving mechanism 410 that moves mold holder 400 between first to third units 100, 200, 300. Mold holder 400 is also fitted with second moving mechanism 420 that moves mold holder 400 toward each of first stage 110 and second stage 210. When third unit 300 is provided outside processing apparatus 600, first moving mechanism 410 moves mold holder 400 between first unit 100 and second unit 200.

Mold holder 400 is fitted with pressurization mechanism 430. Pressurization mechanism 430 pressurizes mold holder 400 positioned immediately above second stage 210 toward second stage 210 with a predetermined pressure. For example, a known load cell is incorporated in pressurization mechanism 430. Pressurization mechanism 430 may be incorporated in second moving mechanism 420.

Controller 500 includes at least one or a plurality of central processing units (CPU) and a storage including a semiconductor memory or the like (none of which is illustrated). Controller 500 controls the respective operations of first material supply mechanism 120, heating mechanism 220, optical exposure system 230, first moving mechanism 410, second moving mechanism 420, and pressurization mechanism 430 described above. Further, controller 500 controls operation of a drive mechanism and a heating mechanism (none of which is illustrated) inside etching chamber 310. Controller 500 may be provided for each unit or each mechanism.

Next, the shape of imprinting mold 50 will be described.

As illustrated in FIG. 3, imprinting mold 50 includes body 51 having a plate shape including first surface 51A and second surface 51B, a plurality of steps 53, and a plurality of pillars 52. First surface 51A and second surface 51B face each other. The plurality of steps 53 project from second surface 51B of body 51. In the example illustrated in FIG. 3, the plurality of pillars 52 project from the bottom surfaces of the plurality of steps 53. Although not illustrated, pillar 52 may project from second surface 51B of body 51. In this case, the tips of all pillars 52 are set to the same position with reference to second surface 51B. In imprinting mold 50, the plurality of steps 53 may be omitted, and only the plurality of pillars 52 may project from second surface 51B.

As described above, imprinting mold 50 is pressed and pressurized against insulation layer 20 using mold holder 400 and pressurization mechanism 430, whereby groove 21 is formed at a position corresponding to step 53, and via hole 22 is formed at a position corresponding to pillar 52 in insulation layer 20. When UV light is used in the imprinting step, the material of imprinting mold 50 is limited to a light transmissive material, but when only thermal imprinting is used, the material of imprinting mold 50 is not limited to this example.

### [Method for Processing Insulation Layer]

FIG. 4 is a schematic view for describing a step of adhering and curing the first material to the tip of the pillar. FIG. 5A is a schematic view for describing a method for processing the insulation layer according to the first exemplary embodiment. FIG. 5B is a schematic view for describing a step subsequent to FIG. 5A. For convenience of description, only first stage 110, second stage 210, heating mechanism 220, and imprinting mold 50 in processing apparatus 600 are illustrated in FIGS. 4, 5A, and 5B, and illustration of other components is omitted.

In the example described below, as insulation layer 20, a photosensitive polyimide-based resin having thermoplasticity is used in a B stage. The B stage is an intermediate stage of the reaction of the thermosetting resin, and refers to a stage in which the thermosetting resin is softened to increase fluidity through heating.

First, a step of adhering and curing first material 60 to the tip of pillar 52 will be described.

As illustrated in FIG. 4, first material 60 is supplied to the upper surface of first stage 110 provided in first unit 100 of processing apparatus 600 (first material supply step). The material of first material 60 is any of the materials described above. First material 60 is applied to the upper surface of first stage 110 by a spin coating method. At this point, first material 60 is in a liquid state or a highly flowable state. In the present exemplary embodiment, the elastic modulus of first material 60 after curing is from 10 kPa to 10 MPa inclusive. The elastic modulus is more preferably from 500 kPa to 5 MPa inclusive.

Next, mold holder 400 is moved to first unit 100 and lowered toward first stage 110 by first moving mechanism 410 and second moving mechanism 420, and first material 60 is adhering to the tip of pillar 52 of imprinting mold 50 mounted on mold holder 400 (first material adhesion step).

First material 60 is a material containing a resin, and its elastic modulus after curing is equal to or lower than the elastic modulus of the resin material constituting insulation layer 20. In the present exemplary embodiment, first material 60 is made only of resin.

The resin in first material 60 is appropriately set in combination with the resin constituting insulation layer 20. Insulation layer 20 functions as an interlayer insulation layer that insulates wirings 11 of the same layer or different layers in redistribution layer 10 and interposer 40. To suppress signal delay and attenuation inside interposer 40, a low dielectric resin material is usually selected as insulation layer 20. For example, a polyimide-based resin or an epoxy-based resin is selected, but in consideration of deformation through imprinting as described later, insulation layer 20 is preferably made of a polyimide-based resin material. Depending on the type of the polyimide-based resin, the elastic modulus after complete curing is about 2000 MPa.

As the resin contained in first material 60, general rubber (elastic modulus at normal temperature: about 1 MPa) or a replica mold resin having an elastic modulus of about from 2 MPa to 6 MPa inclusive is used. The resin is not limited to this, and the thermoplastic resin (elastic modulus at the time of thermal imprinting: several tens of Pa to 10 kPa) or the like used in thermal imprinting described later may be used. The elastic modulus of first material 60 during execution of the imprinting step described later is preferably from 100 kPa to 2 MPa inclusive.

After first material 60 is adhering to the tip of pillar 52, mold holder 400 and imprinting mold 50 are pulled upward by second moving mechanism 420. Further, first material 60 is cured by first material curing mechanism 130 to form adhering substance 61 (adhering substance formation step).

As illustrated in FIG. 5A, in second unit 200, the upper surface of base 30 is pretreated by the above-described surface treatment mechanism (base pretreatment step). This pretreatment is a treatment for cleaning and hydrophilizing the upper surface of base 30. As the cleaning treatment or the hydrophilic treatment, plasma irradiation treatment may be performed on the upper surface of base 30 as illustrated in FIG. 5A.

Next, insulation resin 20A is applied to the upper surface of pretreated base 30 by an application apparatus (not illustrated) provided outside processing apparatus 600 (resin application step). Subsequently, heating mechanism 220 heats second stage 210 to volatilize the solvent contained in insulation resin 20A and preliminarily cure insulation layer 20 (insulation layer pre-curing step). The step illustrated in FIG. 4 and the step illustrated in FIG. 5A may be simultaneously performed inside processing apparatus 600 or may be performed at different timings.

After each step shown in FIGS. 4 and 5A is performed, as illustrated in FIG. 5B, insulation layer 20 is softened while base 30 is heated at a predetermined temperature (insulation layer softening step). That is, insulation layer 20 is set to the above-described B stage. Meanwhile, second moving mechanism 420 is operated to move mold holder 400 and imprinting mold 50 attached to mold holder 400 toward insulation layer 20.

Further, imprinting mold 50 is moved, and the tip of pillar 52 is pressed against the upper surface of insulation layer 20 and pressurized downward with a predetermined pressure (pressurization step). After pillar 52 and step 53 are inserted into softened insulation layer 20 and the tip of pillar 52 reaches the upper surface of base 30, optical exposure system 230 irradiates insulation layer 20 with UV light (photocuring step). The pressurization step until the tip of pillar 52 reaches the upper surface of base 30 may be referred to as imprinting step. The imprinting step according to the present exemplary embodiment uses both thermal imprinting and optical imprinting.

After the irradiation time with the UV light reaches a predetermined time, second moving mechanism 420 is operated to extract imprinting mold 50 from insulation layer 20 (mold release step). After the mold release step is completed, via hole 22 is formed at a position where pillar 52 is inserted in insulation layer 20, and groove 21 is formed at a position where step 53 is inserted.

Further, the insulation layer of base 30 is finally cured (main curing step). The main curing step is performed by heating base 30 on which insulation layer 20 having a plurality of grooves 21 and a plurality of via holes 22 is formed at a predetermined temperature for a predetermined time with a heating apparatus (not illustrated) provided outside processing apparatus 600.

In the present exemplary embodiment, insulation layer 20 is photocured through UV light irradiation through imprinting mold 50 during the thermal imprinting. However, insulation layer 20 may be photocured through UV light irradiation after imprinting mold 50 is released. In this case, it is not necessary to use a light transmissive material as the material of imprinting mold 50, and the options of materials constituting imprinting mold 50 are widened. However, in the latter case, the crosslinking reaction with UV light does not occur, and thus, base 30 is cooled to lower the fluidity, and then imprinting mold 50 is released.

Alternatively, only the optical imprinting method may be used. Insulation layer 20 is made of a resin material having photocurability and thermosetting property. In this case, the pre-curing step can be omitted. However, when insulation resin 20A is supplied in a liquid form to the upper surface of base 30, insulation resin 20A may be heated using heating mechanism 220 for the purpose of decreasing the fluidity of insulation resin 20A.

Next, a problem in the case of forming via hole 22 in insulation layer 20 using imprinting mold 50 will be described with reference to FIGS. 6A to 6C.

FIG. 6A is an enlarged view of the insulation layer in which a groove and a via hole are formed. FIG. 6B is a schematic view for describing a conventional problem, corresponding to FIG. 6A. FIG. 6C is another schematic view for describing a conventional problem, corresponding to FIG. 6A.

In insulation layer 20 finally cured after imprinting, as illustrated in FIG. 6A, groove 21 having the same depth as the height of step 53 with reference to the upper surface of insulation layer 20 is originally formed. In addition, via hole 22 having the same depth as the length of pillar 52 is formed so as to reach TGV electrode 32 exposed on the upper surface of base 30 or a land electrode (not illustrated) from the bottom surface of groove 21.

However, actually, there may be some cases where via hole 22 does not reach TGV electrode 32 or the land electrode, and remaining film 20B of about zero point several μm to several μm remains on the upper surface of base 30 at the bottom of via hole 22.

For example, when base 30 is warped, the upper surface of base 30 may be inclined from a set initial position, as illustrated in FIG. 6B. Also when there is a variation in the thickness of base 30 or when the flatness of the upper surface of base 30 is not good, the upper surface of base 30 is locally inclined from the set initial position.

When such a situation occurs, the relative distance between the tip of pillar 52 and the upper surface of base 30 varies, and a portion where the tip of pillar 52 does not reach the surface of base 30 occurs. As a result, in some of via holes 22, remaining film 20B described above remains at the bottom of via holes 22.

In addition, when TGV electrode 32 is formed, the metal adhering to the upper surface of glass base 31 may be removed by a chemical mechanical polishing (CMP) method or the like. In this case, when the width of TGV electrode 32 increases, a phenomenon called dishing occurs, and the central portion of TGV electrode 32 may be recessed.

When such a recess is generated, a portion where the thickness of insulation layer 20 with reference to the upper surface is larger than the design value is generated, and the tip of pillar 52 does not reach the surface of base 30 as illustrated in FIG. 6C. As a result, remaining film 20B described above remains at the bottom of via hole 22.

The inventors of the present application have found that the above-described problem can be solved by performing imprinting in a state where adhering substance 61 having an elastic modulus less than or equal to the elastic modulus of insulation layer 20 is adhering to the tip of pillar 52. This will be further described below.

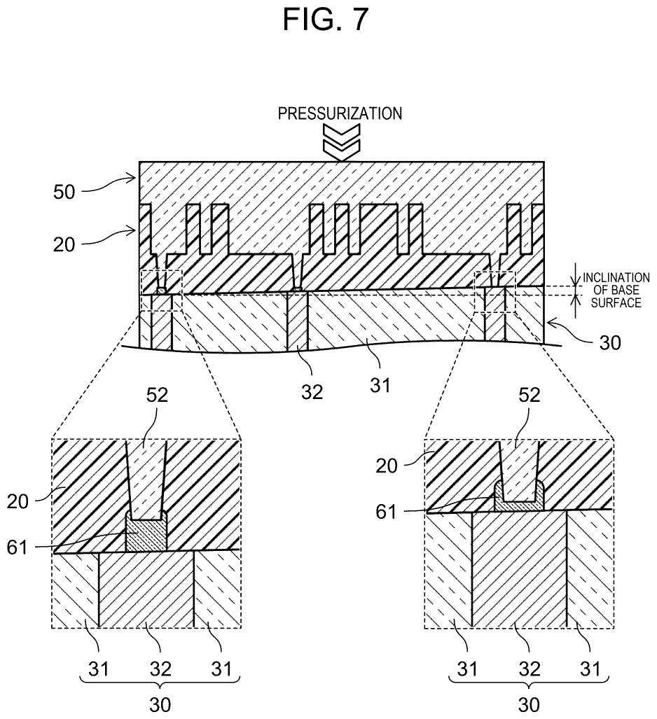

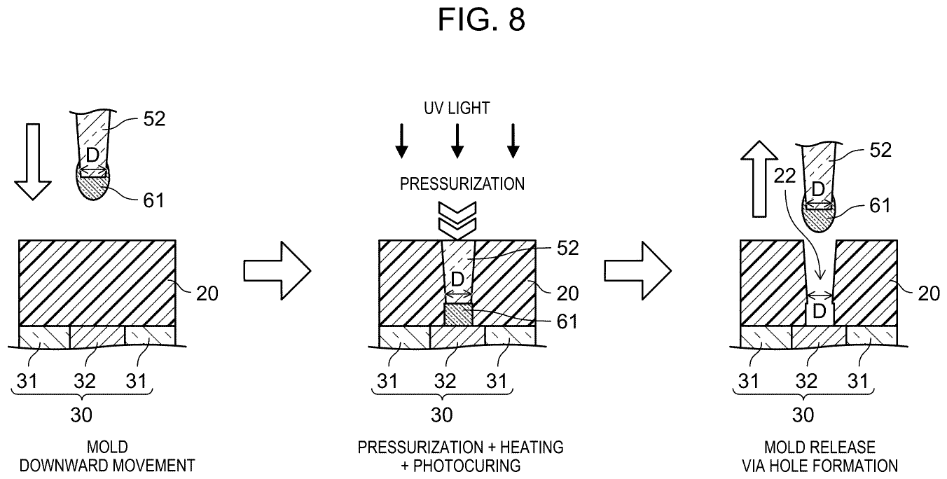

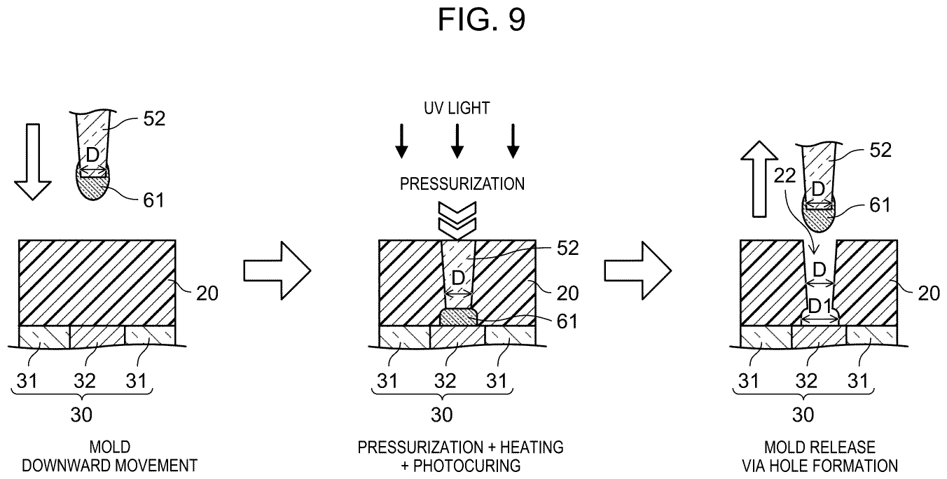

FIG. 7 is an enlarged view of a portion including the tip of the pillar in the pressurization step according to the first exemplary embodiment. FIG. 8 is a schematic view illustrating an outline of a via hole formation step according to the first exemplary embodiment. FIG. 9 is a schematic view illustrating an outline of the via hole formation step according to the first exemplary embodiment, which is a schematic view illustrating a case where a deformation amount of the adhering substance is large.

In the example illustrated in FIG. 7, similarly to the example illustrated in FIG. 6B, the upper surface of base 30 is inclined from the set initial position. Thus, the relative distance between the tip of pillar 52 and the upper surface of base 30 varies in a direction along the upper surface of insulation layer 20.

On the other hand, as illustrated in FIG. 7, adhering substance 61 is adhering to the tip of pillar 52. The length of adhering substance 61 along a length direction of pillar 52 substantially corresponds to the thickness of first material 60 supplied to first stage 110. Thus, when this length is set to about 1 μm to several μm, the tip position of pillar 52 approaches the upper surface of base 30 in a pseudo manner by about 1 μm to several μm. In this state, when pillar 52 is inserted into insulation layer 20 with the pressure appropriately set, the above-described variation in the relative distance can be absorbed, and adhering substance 61 can be caused to reach the upper surface of base 30. That is, the thickness of remaining film 20B at the bottom of via hole 22 can be made less than or equal to a predetermined value.

In addition, because the elastic modulus of adhering substance 61 is less than or equal to the elastic modulus of insulation layer 20, adhering substance 61 is greatly deformed and expands via hole 22 in a portion where the relative distance between the tip of pillar 52 and the upper surface of base 30 is shorter than the thickness of insulation layer 20 (see the enlarged view on the right side of FIG. 7). This makes it possible to prevent damage to pillars 52 while causing adhering substance 61 to reach the upper surface of base 30. In addition, because adhering substance 61 is made of a low elastic material, the shape returns to the original shape when pillar 52 is extracted even though adhering substance 61 is deformed by pushing and expanding via hole 22, and adhering substance 61 is extracted together with pillar 52. Thus, adhering substance 61 does not remain at the bottom of via hole 22.

In addition, as illustrated in FIG. 8, when adhering substance 61 is caused to adhere only to the lower surface of the tip of pillar 52, diameter D of via hole 22 can be made the same as diameter D of pillar 52. That is, the diameter of via hole 22 can be easily controlled. On the other hand, as illustrated in FIG. 9, when adhering substance 61 is greatly deformed at the bottom of via hole 22, diameter D1 of the bottom of via hole 22 becomes larger than diameter D of via hole 22 at the upper portion thereof (D1>D). Because diameter D1 is increased, the contact area between via 12 and TGV electrode 32 is widened when via 12 is formed in a step described later, and the resistance of via 12 can be reduced. However, in this case, because above-described barrier layer 14 and seed layer 15 are less likely to adhere to the inner wall surface of via hole 22 at the bottom of via hole 22, it is necessary to pay attention to the range of diameter D1, in other words, control of the adhesion amount of adhering substance 61.

### [Method for Producing Redistribution Layer]

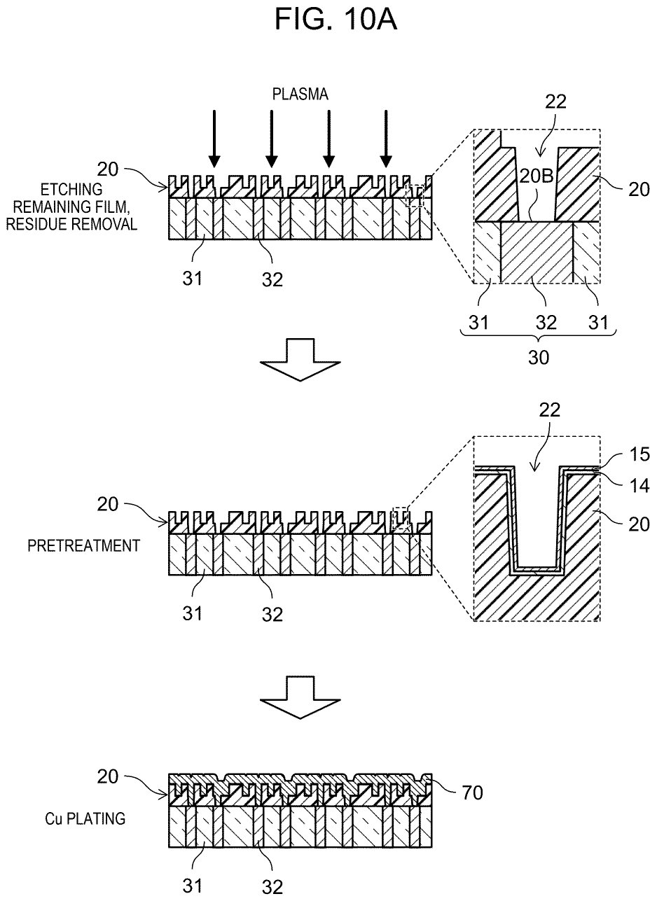

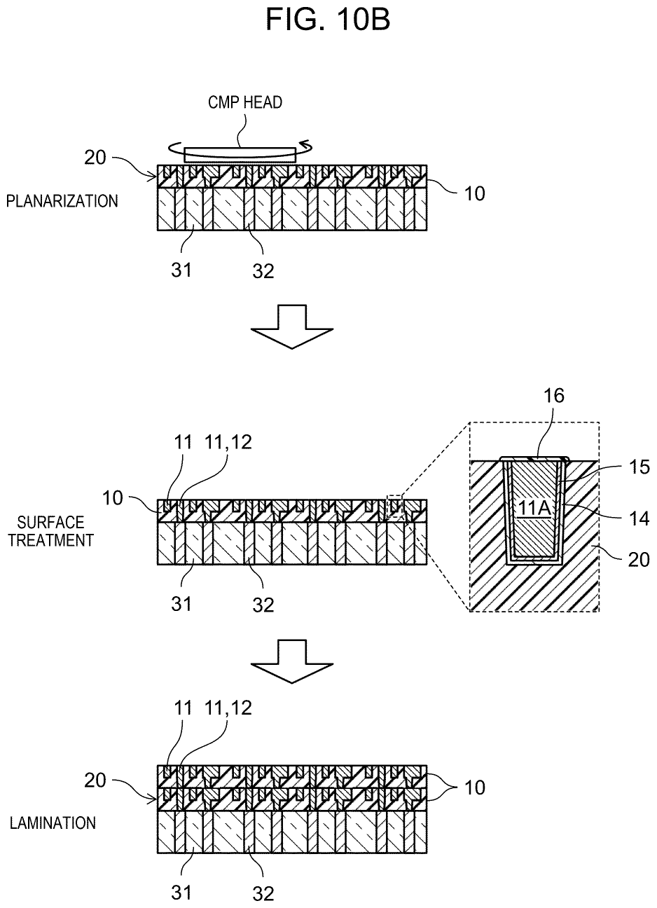

After a plurality of grooves 21 and a plurality of via holes 22 of insulation layer 20 formed on the upper surface of base 30 are formed through the steps illustrated in FIGS. 5A and 5B, redistribution layer 10 is formed by performing the steps illustrated in FIGS. 10A and 10B. The steps illustrated in FIGS. 10A and 10B are performed with a processing apparatus different from processing apparatus 600.

FIG. 10A is a schematic view for describing a method for producing a redistribution layer according to the first exemplary embodiment. FIG. 10B is a schematic view for describing a step subsequent to FIG. 10A.

First, as illustrated in FIG. 10A, a plasma etching treatment is performed on insulation layer 20 in which a plurality of grooves 21 and a plurality of via holes 22 are formed (etching step). By performing this step, as illustrated in FIG. 10A, remaining film 20B of less than or equal to zero point several μm remaining at the bottom of via hole 22 can be reliably removed, and the upper surface of TGV electrode 32 can be exposed. Even when there is no remaining film 20B, depending on the size of the surface unevenness of adhering substance 61, the residue of insulation layer 20 may remain in a size of about several tens of nm on the upper surface of TGV electrode 32. Such residues can also be reliably removed by the etching treatment.

Next, a reverse sputtering treatment is performed on the upper surface of base 30 exposed at insulation layer 20 and the bottom of via hole 22. The reverse sputtering treatment is a treatment of irradiation with inert gas ions, typically argon ions, to remove the surface of insulation layer 20 or base 30 or a substance adhering to the surface. After the reverse sputtering treatment is performed, barrier layer 14 and seed layer 15 are continuously formed on the upper surface of base 30 exposed to insulation layer 20 and the bottom of via hole 22 (pretreatment step).

Usually, the treatments from the reverse sputtering to the formation of seed layer 15 are continuously performed in a sputtering apparatus. That is, barrier layer 14 and seed layer 15 are each formed by a sputtering method. Barrier layer 14 and seed layer 15 are formed in different chambers. However, the treatments are not particularly limited to this example, and barrier layer 14 and seed layer 15 may be formed by a CVD method. In addition, the treatments from the reverse sputtering to the formation of barrier layer 14 may be continuously performed in the same vacuum apparatus, and seed layer 15 may be formed in another apparatus.

After the pretreatment step is performed, base 30 on which insulation layer 20 is formed is introduced into a plating tank (not illustrated), and a metal of the same type as seed layer 15, in this case, Cu plated layer 70 is formed on the surface of seed layer 15 by electrolytic plating (Cu plating step). Plating is performed until Cu plated layer 70 has a thickness enough to sufficiently embed groove 21 and via hole 22. The metal to be plated is not particularly limited to copper. When metal other than copper is plated, it is preferable to use the same type of metal as the metal to be plated as seed layer 15. Groove 21 and via hole 22 may be embedded with metal by using electroless plating.

Next, Cu plated layer 70 deposited on the upper surface of insulation layer 20 is removed. In the present exemplary embodiment, Cu plated layer 70 deposited on the upper surface of insulation layer 20 is polished and removed by a CMP method to planarize the upper surface of insulation layer 20 (planarization step). However, the step is not particularly limited to this example, and for example, Cu plated layer 70 deposited on the upper surface of insulation layer 20 may be cut and removed using a surface planer to planarize the upper surface of insulation layer 20. By removing Cu plated layer 70 deposited on the upper surface of insulation layer 20, copper (Cu) embedded in groove 21 is processed into wiring 11, and copper embedded in via hole 22 is processed into via 12.

After the planarization treatment is performed, surface protective layer 16 is formed so as to cover the upper surface of wiring 11 exposed on the upper surface of insulation layer 20 (surface treatment step). Usually, an inorganic insulation film or an inorganic conductive film to be surface protective layer 16 is formed on the entire upper surface of insulation layer 20, and then a portion excluding the upper surface of wiring 11 is removed by photolithography and etching using a photomask (not illustrated). As described above, instead of the surface treatment step of forming surface protective layer 16, a treatment such as applying a corrosion inhibitor to the upper surface of wiring 11 may be performed.

After the steps described above are performed, redistribution layer 10 is obtained. As necessary, redistribution layer 10 is laminated by performing the treatments illustrated in FIGS. 5A and 5B and FIGS. 10A and 10B on the upper surface of redistribution layer 10 that has been formed (lamination step). After redistribution layers 10 of the necessary number of layers are formed, an electrode for external connection (not illustrated) is formed on the surface of TGV electrode 32 or the land electrode exposed on the lower surface of base 30 to complete interposer 40.

### [Effects and the Like]

As described above, the method for processing insulation layer 20 according to the present exemplary embodiment uses imprinting mold 50 including body 51, a plurality of steps 53, and a plurality of pillars 52. The plurality of steps 53 project from second surface 51B of body 51, and the plurality of pillars 52 project from the bottom surfaces of the plurality of steps 53. Pillar 52 may project from second surface 51B of body 51. In imprinting mold 50, the plurality of steps 53 may be omitted, and only the plurality of pillars 52 may project from second surface 51B.

The method for processing insulation layer 20 includes at least a plurality of steps described below.

In the insulation layer formation step, insulation layer 20 is formed on the upper surface of base 30.

In the first material adhesion step, first material 60 is caused to adhere to the tip of pillar 52. First material 60 adhering to the tip is cured to become adhering substance 61.

In the pressurization step, imprinting mold 50 is pressed and pressurized against insulation layer 20 so that adhering substance 61 reaches the upper surface of base 30.

In the mold release step, imprinting mold 50 is extracted from insulation layer 20 to form via hole 22 at the position where pillar 52 is inserted in insulation layer 20, and form groove 21 at the position where step 53 is inserted. When the plurality of steps 53 are omitted in imprinting mold 50, groove 21 is not formed, but only via hole 22 is formed in the mold release step.

In the curing step, insulation layer 20 is cured. The curing step includes the photocuring step with UV light and the main curing step.

The elastic modulus of first material 60 and adhering substance 61 which is a cured product of the first material is equal to or lower than the elastic modulus of insulation layer 20.

According to the present exemplary embodiment, even when the relative distance between the tip of pillar 52 and the upper surface of base 30 varies due to warping of base 30, dishing of TGV electrode 32, or the like, the variation in the relative distance can be absorbed, and the thickness of remaining film 20B at the bottom of via hole 22 can be made less than or equal to a predetermined value. As a result, the bottom of via hole 22 can be reliably opened by the subsequent etching treatment. In addition, in redistribution layer 10 formed by embedding a metal such as copper in groove 21 and via hole 22, it is possible to reduce an electrical connection failure with base 30 or another redistribution layer 10 provided below the redistribution layer.

When insulation layer 20 is a polyimide-based resin or an epoxy-based resin, the elastic moduli of first material 60 and adhering substance 61 are preferably sufficiently lower than the elastic moduli of the polyimide-based resin and the epoxy-based resin (about several hundred MPa to several thousand MPa). For example, the elastic moduli of first material 60 and adhering substance 61 in the imprinting step are preferably from 10 kPa to 10 MPa inclusive, and more preferably from 100 kPa to 2 MPa inclusive.

With such elastic moduli, adhering substance 61 greatly deforms and push and expand via hole 22, and thus pillar 52 can be prevented from being damaged while adhering substance 61 reaches the upper surface of base 30.

In addition, in the mold release step in the present exemplary embodiment, imprinting mold 50 is extracted from insulation layer 20 with adhering substance 61 adhering to the tip of pillar 52.

With this step, adhering substance 61 does not remain at the bottom of via hole 22, and the upper surface of base 30 can be reliably exposed at the bottom of via hole 22 through the subsequent etching treatment.

When insulation layer 20 has thermoplasticity, the material constituting imprinting mold 50, adhering substance 61, and insulation layer 20 have elastic moduli in descending order in the pressurization step.

On the other hand, in the mold release step, the material constituting imprinting mold 50, insulation layer 20, and adhering substance 61 have elastic moduli in descending order.

By defining the magnitude of the elastic moduli in this manner, imprinting mold 50 can be reliably embedded in insulation layer 20 in the pressurization step. In addition, after the mold release step is performed, the thickness of remaining film 20B at the bottom of via hole 22 can be made less than or equal to a predetermined value.

First material 60 and adhering substance 61 are preferably made of a low water-repellent material. This makes it possible to further suppress the generation of remaining film 20B or the generation of residues at the bottom of via hole 22 caused by insulation layer 20 coming around the bottom.

First material 60 and adhering substance 61 are preferably made of a material having high releasability. This makes it easy to insert imprinting mold 50 into insulation layer 20 in the pressurization step. In addition, imprinting mold 50 can be easily extracted from insulation layer 20 in the mold release step.

The method for producing redistribution layer 10 according to the present exemplary embodiment includes at least a plurality of steps shown below.

In the recess formation step, a plurality of grooves 21 and a plurality of via holes 22 are formed in insulation layer 20 formed on the upper surface of base 30 using the above-described method for processing insulation layer 20.

In the pretreatment step, barrier layer 14 and seed layer 15 are formed on the surface of insulation layer 20 including the respective inner wall surfaces of the plurality of grooves 21 and the plurality of via holes 22.

In the plating step, metal plating is performed on the surface of seed layer 15 to embed metal in grooves 21 and via holes 22.

In the planarization step, the metal embedded in groove 21 is processed into wiring 11, and the metal embedded in via hole 22 is processed into via 12 by removing the metal formed on the upper surface of insulation layer 20.

When the plurality of steps 53 are omitted in imprinting mold 50, groove 21 is not formed but only via hole 22 is formed in the recess formation step. In the pretreatment step, barrier layer 14 and seed layer 15 are formed on the surface of insulation layer 20 including the inner wall surface of each of the plurality of via holes 22. In the plating step, metal plating is performed on the surface of seed layer 15 to embed metal in via hole 22. In the planarization step, the metal embedded in via hole 22 is processed into via 12 by removing the metal formed on the upper surface of insulation layer 20.

According to the present exemplary embodiment, in redistribution layer 10, via 12 can be reliably exposed on the lower surface of insulation layer 20. This makes it possible to reduce an electrical connection failure between redistribution layer 10 and base 30 or another redistribution layer 10 provided below the redistribution layer.

In addition, a lamination step of laminating a plurality of redistribution layers in a thickness direction by repeatedly executing a series of treatments from the recess formation step to the planarization step may be further included. This makes it possible to easily produce interposer 40 including redistribution layer 10 having a multilayer structure.

Processing apparatus 600 according to the present exemplary embodiment is an apparatus for forming a plurality of grooves 21 and a plurality of via holes 22 in insulation layer 20 formed on the upper surface of base 30. Processing apparatus 600 includes at least first unit 100, second unit 200, and mold holder 400.

First unit 100 includes at least first stage 110 and first material supply mechanism 120. First material supply mechanism 120 supplies first material 60 such that the first material spreads over a predetermined range on the upper surface of first stage 110.

Second unit 200 includes at least second stage 210 for placing base 30 on which insulation layer 20 is formed, and heating mechanism 220 for heating second stage 210.

Mold holder 400 is fitted with first moving mechanism 410 and second moving mechanism 420. First moving mechanism 410 moves mold holder 400 at least between first unit 100 and second unit 200. Second moving mechanism 420 moves mold holder 400 toward each of first stage 110 and second stage 210.

Imprinting mold 50 is detachably attached to the lower end of mold holder 400.

In first unit 100, first material 60 is caused to adhere to the tips of the plurality of pillars 52 provided in imprinting mold 50.

In second unit 200, mold holder 400 presses and pressurizes imprinting mold 50 to which adhering substance 61 obtained by curing first material 60 is adhering against insulation layer 20, whereby a plurality of grooves 21 and a plurality of via holes 22 are formed in insulation layer 20. When the plurality of steps 53 are omitted in imprinting mold 50, the plurality of via holes 22 are formed in insulation layer 20 in second unit 200.

By configuring processing apparatus 600 in this manner, the thickness of remaining film 20B at the bottom of via hole 22 can be made less than or equal to a predetermined value. As a result, the bottom of via hole 22 can be reliably opened by the subsequent etching treatment. In addition, in redistribution layer 10 formed by embedding a metal such as copper in groove 21 and via hole 22, it is possible to reduce an electrical connection failure with base 30 or another redistribution layer 10 provided below the redistribution layer.

Preferably, first unit 100 further includes first material curing mechanism 130 that cures first material 60 adhering to pillar 52 into adhering substance 61. This makes it possible to reliably fix and adhere adhering substance 61 which is a low elastic material to the tip of pillar 52.

When imprinting mold 50 is made of a light transmissive material, and insulation layer 20 is made of a photocurable material, second unit 200 preferably further includes optical exposure system 230. Optical exposure system 230 irradiates insulation layer 20 with light through imprinting mold 50.

By providing optical exposure system 230, insulation layer 20 can be cured by irradiating insulation layer 20 with light during the pressurization step or immediately after the pressurization step. This makes it possible to suppress deformation of the shapes of groove 21 and via hole 22.

Processing apparatus 600 may further include third unit 300. In third unit 300, after a plurality of grooves 21 and a plurality of via holes 22 are formed in insulation layer 20, adhering substance 61 adhering to imprinting mold 50 is removed. When the plurality of steps 53 are omitted in imprinting mold 50, in third unit 300, adhering substance 61 adhering to imprinting mold 50 is removed after a plurality of via holes 22 are formed in insulation layer 20.

By providing third unit 300, imprinting mold 50 can be continuously used without being detached from mold holder 400. This can reduce downtime of processing apparatus 600. In addition, because adhering substance 61 adhering to imprinting mold 50 can be removed at an appropriate timing, the amount of adhering substance 61 at the tip of pillar 52 can be kept constant, and variation in the extrusion amount of insulation layer 20 can be suppressed in the pressurization step. This makes it possible to suppress variations in the shape of via holes 22.

### Modification

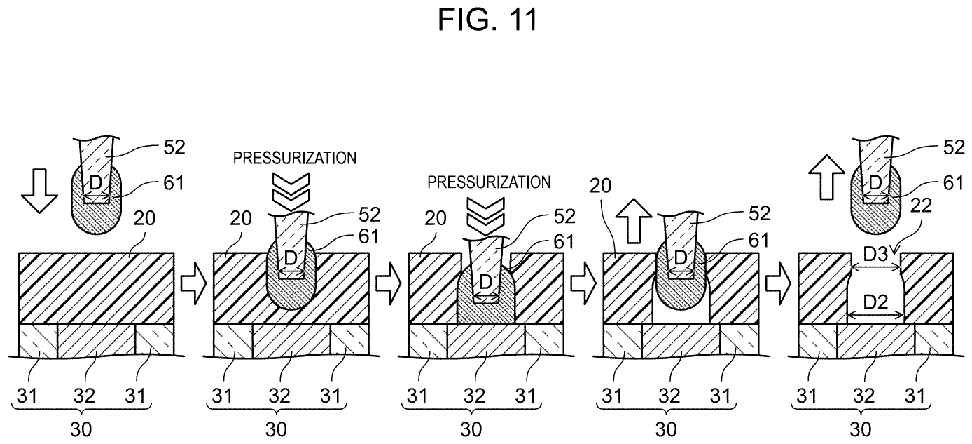

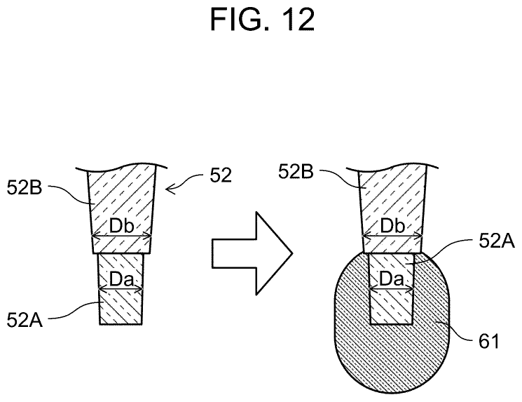

FIG. 11 is a schematic view illustrating an outline of a via hole formation step according to a modification. FIG. 12 is a schematic sectional view of a tip of another pillar according to the modification. For the sake of convenience in description, FIG. 11 and subsequent drawings denote parts similar to the parts of the first exemplary embodiment with the same reference marks, and details thereof will not be described.

In the via hole formation step illustrated in FIG. 11, the range of adhering substance 61 covering the tip of pillar 52 is different from that in the via hole formation step illustrated in FIG. 8. As illustrated in the leftmost diagram of FIG. 11, adhering substance 61 is adhering to the tip of pillar 52 so as to cover not only the lower surface but also the outer peripheral surface.

Thus, when pillar 52 is inserted into insulation layer 20 in the pressurization step, insulation layer 20 in a range larger than diameter D of pillar 52 is pushed out by adhering substance 61. Further, the diameter of via hole 22 formed in insulation layer 20 after the mold release step is performed is larger than diameter D of pillar 52.

According to the present modification, by causing adhering substance 61 to adhere to the tip of pillar 52 so as to cover the outer peripheral surface at the tip and appropriately adjusting the attachment amount, specifically, the width of adhering substance 61, the diameter of via hole 22 can be increased with reference to diameter D of pillar 52. As a result, the resistance of via 12 can be changed according to the design specification of redistribution layer 10 and thus the design specification of the interposer 40. The adhesion amount of adhering substance 61 can be adjusted, for example, by repeating the step illustrated in FIG. 4 a plurality of times.

As illustrated in FIG. 11, when the length of adhering substance 61 along a longitudinal direction of pillar 52 is shorter than the thickness of insulation layer 20 and the deformation amount of adhering substance 61 abutting on the upper surface of base 30 is large, diameter D3 of the bottom of via hole 22 may be larger than diameter D2 of the upper portion. Thus, it is necessary to set the adhesion amount of adhering substance 61 according to the desired diameter of via hole 22 and the allowable amount of change in the diameter.

In addition, when adhering substance 61 is adhering to the tip of pillar 52 so as to cover the outer peripheral surface, first material 60 unintentionally comes up to the upper side, and the amount and width of adhering substance 61 may not be appropriately set. To control such coming up, for example, the tip of pillar 52 may have a shape illustrated in FIG. 12.

The tip of pillar 52 illustrated in FIG. 12 has first portion 52a and second portion 52b. Second portion 52b is provided above first portion 52a, that is, at a position close to body 51. Diameter Db of second portion 52b is larger than diameter Da of first portion 52a.

By forming the tip of pillar 52 into the shape illustrated in FIG. 12, in the first material adhesion step, the coming up of first material 60 is blocked by a step provided as a difference in diameter between first portion 52a and second portion 52b. That is, adhering substance 61 covers the outer peripheral surface of first portion 52a and adheres to pillar 52, but does not adhere to second portion 52b.

Thus, by appropriately setting first portion 52a along the longitudinal direction of pillar 52 and diameters Da and Db, it is possible to prevent first material 60 from unintentionally coming up and to set the adhesion amount and the width of adhering substance 61 to desired values.

### Second Exemplary Embodiment

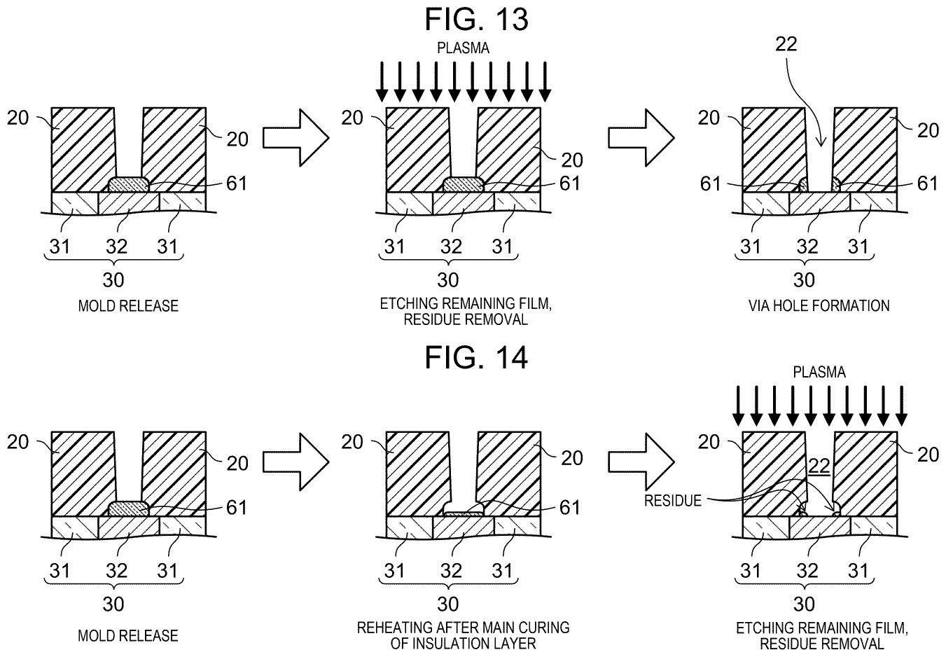

FIG. 13 is a schematic view illustrating an outline of a via hole formation step according to a second exemplary embodiment. FIG. 14 is a schematic view illustrating an outline of another via hole formation step according to the second exemplary embodiment.

In the first exemplary embodiment and the modification, the method of extracting imprinting mold 50 from insulation layer 20 with adhering substance 61 adhering to pillar 52 in the mold release step has been described.

However, the method for processing insulation layer 20 of the present disclosure is not particularly limited to this example, and as illustrated in FIGS. 13 and 14, imprinting mold 50 may be extracted from insulation layer 20 with adhering substance 61 being left at the bottom of via hole 22. In this case, adhering substance 61 left at the bottom of via hole 22 is removed in the etching step subsequent to the mold release step.

In addition, even when adhering substance 61 is deformed, and insulation layer 20 at the bottom of via hole 22 is pushed out and spread, it is possible to leave adhering substance 61 biting into the inner wall surface at the bottom of via hole 22 by performing anisotropic dry etching. As a result, in via hole 22, the difference between the diameter of the bottom and the diameter of the top can be reduced. In addition, when barrier layer 14 and seed layer 15 are formed, insufficient coverage at the bottom of via hole 22 can be improved. As a result, it is possible to reduce a metal embedding failure in via hole 22 in the plating step, to suppress a connection failure between via 12 and TGV electrode 32, the land electrode, or lower layer wiring 11, and to suppress a decrease in connection reliability.

To suppress an increase in the diameter of via hole 22 in the etching step, adhering substance 61 is preferably a material having a higher etching rate than insulation layer 20. For example, first material 60 and adhering substance 61 are preferably made of a resin material having a lower molecular weight than that of insulation layer 20. Alternatively, first material 60 and adhering substance 61 are preferably made of a resin material having a glass transition temperature lower than that of insulation layer 20.

In addition, first material 60 and adhering substance 61 are preferably made of a resin material having a larger film loss amount due to heating than that of insulation layer 20. For example, by increasing the content proportion of the solvent in first material 60 and adhering substance 61, the film loss amount can be increased. In this case, the content proportion of the solvent in first material 60 and the curing condition of first material 60 are set such that the solvent remains in adhering substance 61 at a certain proportion.

In addition, as illustrated in FIG. 14, a heating step of heating insulation layer 20 on which adhering substance 61 is left is provided between the mold release step and the etching step. Since the film of adhering substance 61 is reduced in the heating step, the etching amount of adhering substance 61 and insulation layer 20 can be reduced in the etching step, and the diameter of via hole 22 can be prevented from increasing.

In the example illustrated in FIG. 14, a heating step is provided separately from the main curing step for insulation layer 20, but the heating step described above is omitted as long as adhering substance 61 is sufficiently reduced by heating during the pressurization step or heating in the curing step in the case of adopting an optical imprinting method.

### Third Exemplary Embodiment

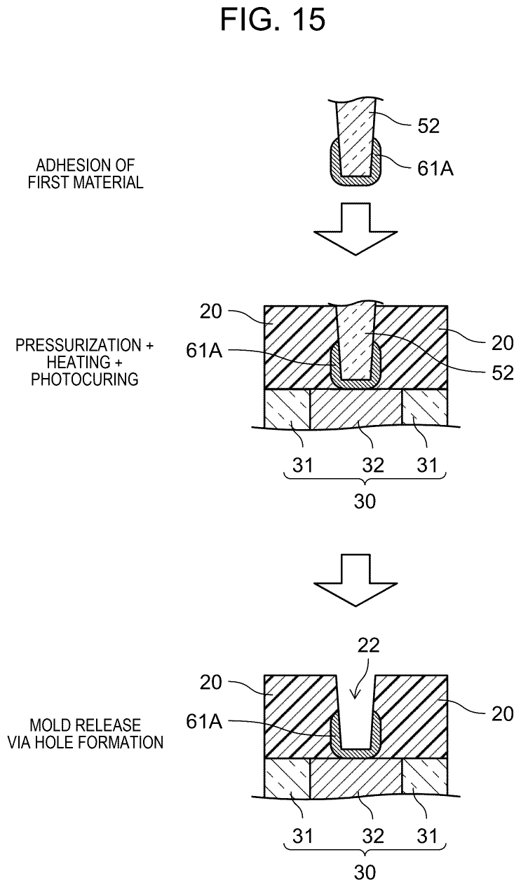

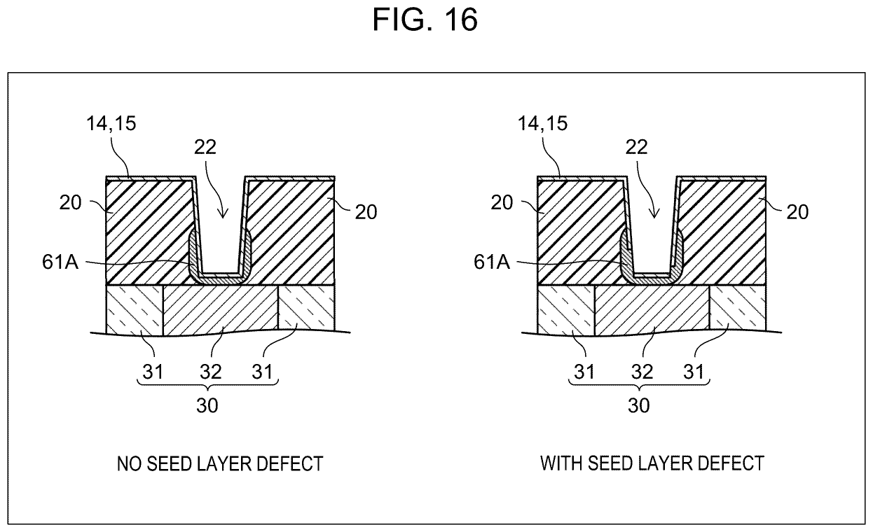

FIG. 15 is a schematic view illustrating an outline of a via hole formation step according to a third exemplary embodiment. FIG. 16 is a schematic sectional view of a via hole after execution of a pretreatment step according to the third exemplary embodiment.

The via hole formation step illustrated in FIG. 15 is different from the via hole formation step of the second exemplary embodiment illustrated in FIG. 13 in that adhering substance 61A is a conductive material. In the present exemplary embodiment, first material 60 is made of a resin material in which fine particles of a conductive material, for example, a nano conductive material is dispersed, whereby conductivity is imparted to adhering substance 61A. The content proportion and the like of the nano conductive material can be appropriately changed according to the electric conductivity and the like required for adhering substance 61A.

In the via hole formation step according to the present exemplary embodiment, as illustrated in FIG. 15, adhering substance 61A is made of a conductive material, and adhering substance 61A is left at the bottom of via hole 22 after the mold release step. In this case, the nano conductive material in adhering substance 61A and TGV electrode 32 are bonded through heating during the pressurization step. In addition, the bonding between insulation layer 20 and adhering substance 61A is also strengthened via the nano conductive material. Thus, adhering substance 61A remains at the bottom of via hole 22 after the mold release step. In this case, as illustrated in FIG. 16, barrier layer 14 and seed layer 15 are formed with adhering substance 61A being left at the bottom of via hole 22.

According to the present exemplary embodiment, the etching treatment for removing adhering substance 61A can be omitted. That is, the number of steps in the method for processing insulation layer 20 and the method for producing redistribution layer 10 can be reduced. In addition, because adhering substance 61A is a conductive material, electrical connection between via 12 and lower wiring 11, TGV electrode 32, or the land electrode can be secured even though adhering substance 61A is left at the bottom of via hole 22.

In addition, as illustrated in the diagram on the right of FIG. 16, defects may occur in barrier layer 14 and seed layer 15 inside via hole 22. In particular, when the aspect ratio of via hole 22, that is, the ratio of the depth to the diameter increases, in a physical vapor deposition method such as a sputtering method, the amount of metal adhering to the inner wall surface at the bottom of via hole 22 decreases, and defects are likely to occur. When such a defect occurs, a metal is not deposited at a defective portion in the subsequent electrolytic plating step, and a metal embedding failure occurs in via hole 22. As a result, an increase in resistance of via 12 or a connection failure between via 12 and wiring 11 in the lower layer of the via or the like may occur. In addition, there is a possibility that connection reliability between via 12 and wiring 11 or the like in the lower layer of the via is lowered.

On the other hand, according to the present exemplary embodiment, even though there is a defect in barrier layer 14 or seed layer 15, metal deposition failure is less likely to occur because adhering substance 61A in the lower layer has conductivity. This makes it possible to suppress metal embedding failure in via hole 22 and to suppress an increase in resistance of via 12 and occurrence of a connection failure between via 12 and wiring 11 or the like in the lower layer of the via. In addition, it is possible to suppress a decrease in connection reliability between via 12 and wiring 11 or the like in the lower layer of the via.

### Other Exemplary Embodiment

Processing apparatus 600 may further include an insulation layer formation mechanism (not illustrated) that forms insulation layer 20 on the upper surface of base 30. This makes it possible to continuously perform the insulation layer formation step and the subsequent steps and to shorten the manufacturing TAT of redistribution layer 10 and thus, the manufacturing TAT of interposer 40. The insulation layer formation mechanism is provided inside second unit 200, for example.

The insulation layer formation mechanism is, for example, a spin coater. However, the mechanism is not particularly limited to this example, and the insulation layer formation mechanism may be a spray coater. Insulation resin 20A, for example, the above-described polyimide-based resin is applied to the entire upper surface of base 30 so as to have a uniform thickness by the insulation layer formation mechanism.

According to the present disclosure, the thickness of the remaining film at the bottom of the via hole provided in the insulation layer of the redistribution layer can be made less than or equal to a predetermined value. In addition, it is possible to reduce electrical connection failure with a base or a redistribution layer provided below the redistribution layer.

The method for processing an insulation layer of the present disclosure is useful because the thickness of the remaining film at the bottom of a via hole provided in the insulation layer of the redistribution layer can be made less than or equal to a predetermined value, and the electrical connection failure between the redistribution layer and the base or the redistribution layer provided below the redistribution layer can be reduced.

What is claimed is:

1. A method for processing an insulation layer, the method using an imprinting mold,
the imprinting mold including at least a body and a plurality of pillars,
wherein the plurality of pillars project from at least a second surface of the body,
the method comprising:
an insulation layer formation step of forming the insulation layer on an upper surface of a base;
a first material adhesion step of causing a first material to adhere to a tip of each of the plurality of pillars;
a pressurization step of pressing and pressurizing the imprinting mold against the insulation layer to cause the first material to reach the upper surface of the base;
a mold release step of extracting the imprinting mold from the insulation layer to form a via hole at a position in the insulation layer where a corresponding one of the plurality of pillars is inserted; and
a curing step of curing the insulation layer,
wherein the first material has an elastic modulus equal to or lower than an elastic modulus of the insulation layer.

2. The method according to claim 1, wherein
the imprinting mold further includes a plurality of steps projecting from the second surface of the body,
the plurality of pillars project from bottom surfaces of the plurality of steps, respectively, and
the mold release step includes extracting the imprinting mold from the insulation layer to form a groove at a position where a corresponding one of the plurality of steps is inserted.

3. The method according to claim 1,
wherein the elastic modulus of the first material is from 10 kPa to 10 MPa inclusive.

4. The method according to claim 3,
wherein the elastic modulus of the first material is from 100 kPa to 2 MPa inclusive.

5. The method according to claim 1,
wherein the mold release step includes extracting the imprinting mold from the insulation layer with the first material adhering to the tip of the pillar.

6. The method according to claim 5, wherein
in the pressurization step, a material constituting the imprinting mold, the first material, and the insulation layer have elastic moduli in descending order, and
in the mold release step, the material constituting the imprinting mold, the insulation layer, and the first material have elastic moduli in descending order.

7. The method according to claim 1,
wherein the mold release step includes extracting the imprinting mold from the insulation layer with the first material being left at a bottom of the via hole.

8. The method according to claim 7,
the method further comprising an etching step of removing the first material left at the bottom of the via hole by etching after execution of the mold release step.

9. The method according to claim 8,
the method further comprising a heating step of heating the insulation layer before execution of the etching step.

10. The method according to claim 7,
wherein the first material is a conductive material.

11. A method for producing a redistribution layer, the method comprising:
a recess formation step of forming at least a plurality of via holes in the insulation layer formed on the upper surface of the base by using the method for processing the insulation layer according to claim 1, each of the plurality of via holes is the via hole;
a pretreatment step of forming a barrier layer and a seed layer on a surface of the insulation layer including an inner wall surface of each of the plurality of via holes;
a plating step of performing metal plating on a surface of the seed layer to embed a metal in each of the plurality of via holes; and
a planarization step of processing the metal embedded in the plurality of via holes into a plurality of vias by removing the metal formed on an upper surface of the insulation layer,
wherein the insulation layer and the plurality of vias constitute the redistribution layer.

12. The method according to claim 11, wherein
the imprinting mold further includes a plurality of steps projecting from the second surface of the body,
the recess formation step includes further forming a plurality of grooves in the insulation layer,
the pretreatment step includes forming the barrier layer and the seed layer on the surface of the insulation layer including an inner wall surface of each of the plurality of grooves and the inner wall surface of each of the plurality of via holes,
the plating step includes performing the metal plating on the surface of the seed layer to embed the metal in the plurality of grooves and the plurality of via holes,
the planarization step includes processing the metal embedded in the plurality of grooves into a plurality of wirings and processing the metal embedded in the plurality of via holes into the plurality of vias by removing the metal formed on the upper surface of the insulation layer, and
the insulation layer, the plurality of wirings, and the plurality of vias constitute the redistribution layer.

13. The method according to claim 11,
the method further comprising a lamination step of laminating a plurality of redistribution layers in a thickness direction by repeatedly executing a series of treatments from the recess formation step to the planarization step, each of the plurality of redistribution layers is the redistribution layer.

14. A processing apparatus for forming at least a plurality of via holes in an insulation layer formed on an upper surface of a base,
the processing apparatus comprising:
a first unit;
a second unit; and
a mold holder,
wherein
the first unit includes:
a first stage; and
a first material supply mechanism that supplies a first material having an elastic modulus equal to or lower than an elastic modulus of the insulation layer to cause the first material to spread in a predetermined range on an upper surface of the first stage,
the second unit includes:
a second stage for placing the base on which the insulation layer is formed; and
a heating mechanism for heating the second stage,
the mold holder is fitted with:
a first moving mechanism that moves the mold holder at least between the first unit and the second unit; and
a second moving mechanism that moves the mold holder toward each of the first stage and the second stage,
an imprinting mold is detachably attached to a lower end of the mold holder, and
the imprinting mold includes:
a body; and
a plurality of pillars projecting from a second surface of the body,
wherein
in the first unit, the first material is caused to adhere to a tip of each of the plurality of pillars, and
in the second unit, the plurality of via holes are formed in the insulation layer by pressing and pressurizing the imprinting mold to which the first material is adhering against the insulation layer, using the mold holder.

15. The processing apparatus according to claim 14, wherein
the imprinting mold further includes a plurality of steps projecting from the second surface of the body,
the plurality of pillars project from bottom surfaces of the plurality of steps, respectively, and
in the second unit, a plurality of grooves and the plurality of via holes are formed in the insulation layer by pressing and pressurizing the imprinting mold to which the first material is adhering against the insulation layer, using the mold holder.

16. The processing apparatus according to claim 14,
wherein the first unit further includes a first material curing mechanism that cures the first material adhering to each of the plurality of pillars.

17. The processing apparatus according to claim 14, wherein
the imprinting mold is made of a light transmissive material,
the insulation layer is made of a photocurable material, and
the second unit further includes an optical exposure system that irradiates the insulation layer with light through the imprinting mold.

18. The processing apparatus according to claim 14,
further comprising a third unit for removing the first material adhering to the imprinting mold after the plurality of via holes are formed in the insulation layer.
